(19) United States
(12) Patent Application Publication
(10) Pub. No.: US 2020/0190672 A1
(43) Pub. Date: Jun. 18, 2020

(54) ETCHING SOLUTION, METHOD FOR PROCESSING OBJECT TO BE PROCESSED, AND METHOD FOR MANUFACTURING SEMICONDUCTOR ELEMENT

(71) Applicant: TOKYO OHKA KOGYO CO., LTD., Kawasaki-shi (JP)

(72) Inventors: Takuya OHHASHI, Kawasaki-shi (JP); Mai SUGAWARA, Kawasaki-shi (JP); Yukihisa WADA, Kawasaki-shi (JP)

(21) Appl. No.: 16/708,009

(22) Filed: Dec. 9, 2019

(30) Foreign Application Priority Data
Dec. 18, 2018 (JP) 2018-236259

(51) Int. Cl. C23F 1/30; H01L 21/306; C23F 4/00; C23F 1/40

(52) U.S. Cl. CPC C23F 1/30; C23F 1/40; C23F 4/00; H01L 21/30604

(57) ABSTRACT

A ruthenium etching solution including orthoperiodic acid and ammonia, the pH of the ruthenium etching solution being 3 or higher. In addition, a method for processing an object to be processed including etching an object to be processed including ruthenium, using the ruthenium etching solution, and a method for manufacturing a semiconductor element.

### BACKGROUND OF THE INVENTION

### Field of the Invention

The present invention relates to an etching solution, a method for processing an object to be processed, and a method for manufacturing a semiconductor element.

Priority is claimed on Japanese Patent Application No. 2018-236259 filed in Japan on Dec. 18, 2018, the contents of which are incorporated herein by reference.

### Description of Related Art

The semiconductor device manufacturing process is formed of various processing steps with multiple stages. Such processing steps also include a process of patterning a semiconductor layer, an electrode, or the like by etching or the like. In recent years, in tandem with the progress regarding higher integration, higher speed, and the like of semiconductor devices, ruthenium (Ru) has been used for wiring and the like. In such a case, the ruthenium is an object to be etched.

As a ruthenium etching solution for carrying out an etching process on ruthenium, for example, a solution including orthoperiodic acid as an oxidizing agent was proposed (Patent Documents 1 and 2).

### PRIOR ART DOCUMENTS

### Patent Literature

[Patent Document 1] International Publication No. 2016/68183

[Patent Document 2] Japanese Unexamined Patent Application, First Publication No. 2016-92101

### SUMMARY OF THE INVENTION

In the etching process in the semiconductor device manufacturing process, there is a demand for an etching solution with a high etching rate. However, it is not possible to say that the ruthenium etching solutions of the related art described in Patent Document 1 or 2 have a sufficient etching rate with respect to ruthenium.

The present invention was made in view of the above circumstances and has an object of providing an etching solution having an improved etching rate with respect to ruthenium, a method for processing an object to be processed using the etching solution, and a method for manufacturing a semiconductor element.

### Means for Solving Problems

In order to solve the problems described above, the present invention adopts the following configurations.

A first aspect of the present invention is a ruthenium etching solution including orthoperiodic acid, which further includes ammonia, and pH of the ruthenium etching solution is 3 or higher.

A second aspect of the present invention is a method for processing an object to be processed, the method including carrying out an etching process on an object to be processed including ruthenium using the ruthenium etching solution.

A third aspect of the present invention is a method for manufacturing a semiconductor element, the method including carrying out an etching process on an object to be processed including ruthenium, using the ruthenium etching solution.

### Effect of the Invention

According to the present invention, it is possible to provide an etching solution having an improved etching rate with respect to ruthenium, a method for processing an object to be processed using the etching solution, and a method for manufacturing a semiconductor element.

### BRIEF DESCRIPTION OF THE DRAWINGS

FIG. 1 is a scatter diagram showing the results of an etching process test on a ruthenium substrate performed using an etching solution according to one embodiment of the present invention and etching solutions of Comparative Examples.

### DETAILED DESCRIPTION OF THE INVENTION

### (Etching Solution)

The etching solution according to the first aspect of the present invention includes orthoperiodic acid and ammonia and has pH of 3 or higher. The etching solution according to the present aspect is used for etching ruthenium.

### <Orthoperiodic Acid>

The etching solution according to the present embodiment includes orthoperiodic acid (H₅IO₆).

It is possible to make ruthenium soluble by changing ruthenium to ruthenium tetroxide (RuO₄) bonded to four oxygen atoms. Orthoperiodic acid is an oxidizing agent which releases oxygen atoms to oxidize ruthenium and the oxidation-reduction potential of orthoperiodic acid has a potential sufficient to oxidize and dissolve ruthenium, thus, it is possible to efficiently oxidize and dissolve ruthenium.

The content of orthoperiodic acid in the etching solution of the present embodiment is not particularly limited, but examples thereof include 0.05 to 8% by mass with respect to the total mass of the etching solution, preferably 0.1 to 7% by mass, more preferably 0.5 to 5% by mass, and even more preferably 0.5 to 3% by mass. When the content of orthoperiodic acid is within the above range, the etching rate with respect to the ruthenium is further improved.

### <Ammonia>

The etching solution according to the present embodiment includes ammonia (NH₃).

The content of ammonia in the etching solution of the present embodiment is not particularly limited as long as the content is such that the pH of the etching solution of the present embodiment is 3 or higher, according to the content of the orthoperiodic acid and the amount of other pH adjusters added as necessary. Preferably, the ammonia is used in a content so as to have a preferable pH range for the etching solution of the present embodiment described below. Examples of the ammonia content include 0.001 to 5% by mass with respect to the total mass of the etching solution, preferably 0.002 to 4% by mass, and more preferably 0.005 to 2% by mass. When the ammonia content is within the above range, the etching rate with respect to ruthenium is easily improved.

### <Other Components>

The etching solution of the present embodiment may include other components in addition to the components described above as long as the effects of the present invention are not impaired. Examples of other components include water, a water-soluble organic solvent, a pH adjuster, a surfactant, an oxidizing agent, and the like.

In addition, the etching solution of the present embodiment may include, for example, a slurry (metal oxide particles) used in a chemical mechanical polishing (CMP) process, or may not include such a slurry (metal oxide particles).

However, for example, in a case of being used in an application where the etching solution of the present embodiment is applied through a mask to a ruthenium thin film disposed on a substrate to form ruthenium wiring, such a slurry (metal oxide particles) is preferably not included, for the process stability.

### Water

The etching solution of the present embodiment preferably includes water as a solvent for the above components. The water may include trace components inevitably mixed therein. The water used in the etching solution of the present embodiment is preferably water subjected to a purification process such as distilled water, ion-exchanged water, or ultrapure water, and it is more preferable to use ultrapure water typically used in semiconductor manufacturing.

The content of the water in the etching solution of the present embodiment is not particularly limited, but is preferably 80% by mass or more, more preferably 90% by mass or more, and even more preferably 94% by mass or more. In addition, the upper limit is not particularly limited, but is preferably less than 99.95% by mass, more preferably 99.9% by mass or less, and even more preferably 99.5% by mass or less. The etching solution of the present embodiment is preferably an aqueous solution in which the orthoperiodic acid is dissolved in water and which is adjusted to pH 3 or higher with ammonia.

### Water-Soluble Organic Solvent

The etching solution of the present embodiment may contain a water-soluble organic solvent in a range in which the effects of the present invention are not impaired. Examples of water-soluble organic solvents include alcohols (for example, methanol, ethanol, ethylene glycol, propylene glycol, glycerin, 1,3-propanediol, 1,3-butanediol, 1,4-butanediol, diethylene glycol, dipropylene glycol, furfuryl alcohol, and 2-methyl-2,4-pentanediol, and the like), dimethyl sulfoxide, ethers (for example, ethylene glycol dimethyl ether, diethylene glycol dimethyl ether, triethylene glycol dimethyl ether, tetraethylene glycol dimethyl ether, and propylene glycol dimethyl ether), and the like.

In a case where the etching solution of the present embodiment includes a water-soluble organic solvent, the content of the water-soluble organic solvent is preferably 50% by mass or less with respect to the total of the amount of water and the amount of the water-soluble organic solvent, more preferably 30% by mass or less, and even more preferably 10% by mass or less.

### pH Adjuster

The etching solution of the present embodiment may include a pH adjuster in a range which does not depart from the object of the present invention. Here, the “pH adjuster” in the present specification refers to a component other than the ammonia described above and which is capable of adjusting the pH of the liquid.

In addition, the addition amount is arbitrary and the addition amount may be selected after setting the pH to be described below.

As the pH adjuster, it is possible to use an acidic compound or an alkaline compound. Preferable examples of acidic compounds include inorganic acids such as hydrochloric acid, sulfuric acid, and nitric acid, and salts thereof, or organic acids such as acetic acid, lactic acid, oxalic acid, tartaric acid, and citric acid, and salts thereof.

In addition, as the alkaline compound, it is possible to use an organic alkaline compound and an inorganic alkaline compound and suitable examples of the organic alkaline compound include quaternary ammonium salts including organic quaternary ammonium hydroxides, alkylamines such as trimethylamine and triethylamine and salts of derivatives thereof.

Specific examples of the organic quaternary ammonium hydroxide include tetramethylammonium hydroxide (TMAH), bis (2-hydroxyethyl) dimethylammonium hydroxide, tetraethylammonium hydroxide (TEAH), tetrapropylammonium hydroxide, tetrabutylammonium hydroxide, methyltriethylammonium hydroxide, trimethyl (hydroxyethyl) ammonium hydroxide, triethyl (hydroxyethyl) ammonium hydroxide, and the like.

In addition, examples of inorganic alkaline compounds include inorganic compounds including alkali metals or alkaline earth metals and salts thereof. Examples thereof include lithium hydroxide, sodium hydroxide, potassium hydroxide, rubidium hydroxide, cesium hydroxide, and the like.

### Surfactant

The etching solution of the present embodiment may include a surfactant for the purpose of adjusting the wettability of the etching solution with respect to the object to be processed, or the like. As the surfactant, it is possible to use a nonionic surfactant, an anionic surfactant, a cationic surfactant, or an amphoteric surfactant, and these may be used in combination.

Examples of nonionic surfactants include polyalkylene oxide alkylphenyl ether surfactants, polyalkylene oxide alkyl ether surfactants, block polymer surfactants formed of polyethylene oxide and polypropylene oxide, polyoxyalkylene distyrenated phenyl ether surfactants, polyalkylene tribenzylphenyl ether surfactants, acetylene polyalkylene oxide surfactants, and the like.

Examples of anionic surfactants include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, fatty acid salts, and the like. Examples of “salts” include ammonium salt, sodium salt, potassium salt, tetramethylammonium salt, and the like.

Examples of cationic surfactants include a quaternary ammonium salt surfactant, an alkyl pyridium surfactant, and the like.

Examples of amphoteric surfactants include betaine surfactants, amino acid surfactants, imidazoline surfactants, amine oxide surfactants, and the like.

These surfactants are generally commercially available. One kind of surfactant may be used alone. Two or more kinds may be used in combination.

### Oxidizing Agent

The etching solution of the present embodiment may include another oxidizing agent in addition to the orthoperiodic acid described above. Examples of oxidizing agents include transition metal oxide, peroxide, cerium ammonium nitrate, nitrate, nitrite, iodic acid, iodate, periodate, perchlorate, persulfuric acid, persulfate, peracetic acid, peracetic acid salt, permanganic acid compounds, dichromic acid compounds, and the like.

<pH>

The etching solution of the present embodiment has pH of 3 or higher. Adjusting the pH to 3 or higher using ammonia as a pH adjuster makes it possible to obtain a high etching rate with respect to ruthenium. From the viewpoint of obtaining a good etching rate, the pH of the present embodiment is preferably 4 or more, more preferably 4.5 or more, even more preferably 5 or more, and particularly preferably 5.5 or more. The upper limit of the pH of the etching solution of the present embodiment is not particularly limited, but, from the viewpoint of handleability, for example, it is possible to set the upper limit to 12 or lower. The pH of the etching solution of the present embodiment is preferably 11.5 or lower, more preferably 11 or lower, even more preferably 10.5 or lower, and particularly preferably 10 or lower. Examples of the pH range of the etching solution of the present embodiment include pH 3 to 12, preferably pH 4 to 11, more preferably pH 5 to 10.5, and even more preferably pH 5 to 8.

In addition, depending on the application of the etching solution of the present embodiment, the pH may be 7 or lower.

The pH value as described above is a value measured with a pH meter under normal temperature (23° C.) and normal pressure (1 atm).

### <Object to be Processed>

The etching solution of the present embodiment is used for ruthenium etching and an object to be processed including ruthenium is the target of the etching processing. The object to be processed is not particularly limited as long as the object includes ruthenium and examples thereof include a substrate having a ruthenium-containing layer (ruthenium-containing film) or the like. The substrate is not particularly limited and examples thereof include various substrates such as a semiconductor wafer, a glass substrate for a photomask, a glass substrate for a liquid crystal display, a glass substrate for a plasma display, a substrate for a field emission display (FED), a substrate for an optical disk, a substrate for a magnetic disk, and substrate for a magneto-optical disk. As the substrate, a substrate used for semiconductor device production is preferable. In addition to the ruthenium-containing layer and the base material of the substrate, the substrate may have various layers and structures as appropriate, such as, for example, metal wiring, a gate structure, a source structure, a drain structure, an insulating layer, a ferromagnetic layer, a nonmagnetic layer, and the like. In addition, the uppermost layer on the device surface of the substrate does not need to be the ruthenium-containing layer and, for example, the intermediate layer of the multilayer structure may be the ruthenium-containing layer.

The size, thickness, shape, layer structure, and the like of the substrate are not particularly limited and appropriate selection according to the purpose is possible.

The ruthenium-containing layer is preferably a layer containing a ruthenium metal, and more preferably a ruthenium metal film. The thickness of the ruthenium-containing layer on the substrate is not particularly limited and appropriate selection according to the purpose is possible. Examples of the thickness of the ruthenium-containing layer include a range of 1 to 500 nm and 1 to 300 nm.

The etching solution of the present embodiment may be used for performing fine processing of the ruthenium-containing layer in the substrate, may be used for removing ruthenium-containing deposits attached to the substrate, and may be used to remove impurities such as particles from the object to be processed having the ruthenium-containing layer on the surface.

According to the etching solution of the present embodiment described above, since orthoperiodic acid is included as an oxidizing agent and the pH is adjusted to 3 or higher with ammonia, it is possible to realize a high etching rate for ruthenium. Although it is not certain, it is presumed that this is because ammonia makes it hard to deactivate the activity of the periodic acid as an oxidizing agent and promotes the dissolution of ruthenium by forming a complex with ruthenium. Therefore, using the etching solution of the present embodiment makes it possible to suitably perform fine processing of the ruthenium-containing layer, cleaning of the ruthenium substrate, and the like.

### (Method for Processing Object to be Processed)

The method for processing an object to be processed according to the second aspect of the present invention includes a step of carrying out an etching process on the object to be processed including ruthenium, using the etching solution according to the first aspect described above.

Examples of the object to be processed including ruthenium include the same examples as those described in “<Object to be Processed>” in the “(Etching Solution)” described above and preferable examples include a substrate having a ruthenium-containing layer. The method for forming the ruthenium-containing layer on the substrate is not particularly limited and it is possible to use known methods. Examples of such methods include a sputtering method, a chemical vapor deposition (CVD) method, a molecular beam epitaxy (MBE) method, an atomic layer deposition (ALD) method, and the like. The raw material of the ruthenium-containing layer used when forming the ruthenium-containing layer on the substrate is not particularly limited, and appropriate selection thereof is possible according to the film forming method.

### <Step for Carrying Out Etching Process on Object to be Processed>

This step is a step of carrying out an etching process on the object to be processed including ruthenium, using the etching solution according to the first aspect, and includes an operation of bringing the etching solution into contact with the object to be processed. The etching process method is not particularly limited and it is possible to use a known etching method. Examples of such methods include a spray method, an immersion method, a liquid filling method, or the like, without being limited thereto.

In the spray method, for example, the object to be processed is transported or rotated in a predetermined direction, the etching solution according to the first aspect is sprayed into the space such that the etching solution is brought into contact with the object to be processed. As necessary, the etching solution may be sprayed while rotating the substrate using a spin coater.

In the immersion method, the object to be processed is immersed in the etching solution according to the first aspect and the etching solution is brought into contact with the object to be processed.

In the liquid filling method, the etching solution according to the first aspect is placed on the object to be processed and the object to be processed and the etching solution are brought into contact with each other.

It is possible to appropriately select these etching process methods depending on the structure, materials, and the like of the object to be processed. In a case of the spray method or the liquid filling method, it is sufficient if the supply amount of the etching solution to the object to be processed is an amount by which the surface to be processed in the object to be processed is sufficiently wetted by the etching solution.

The purpose of the etching process is not particularly limited and may be fine processing for a surface to be processed of the object to be processed including ruthenium (for example, a ruthenium-containing layer on a substrate), may be removal of a ruthenium-containing deposit attached to the object to be processed (for example, a substrate having a ruthenium-containing layer), or may be cleaning of a surface to be processed of the object to be processed including ruthenium (for example, a ruthenium-containing layer on the substrate).

In a case where the purpose of the etching process is fine processing of the surface to be processed of the object to be processed including ruthenium, normally, the portion not to be etched is covered with an etching mask and the object to be processed and the etching solution are brought into contact with each other. In a case where the purpose of the etching process is the removal of ruthenium-containing deposits attached to the object to be processed, the ruthenium-containing deposits are dissolved by bringing the etching solution according to the first aspect into contact with the object to be processed and it is possible to remove the ruthenium deposits from the object to be processed.

In a case where the purpose of the etching process is to clean the surface to be processed of the object to be processed including ruthenium, the surface to be processed is rapidly dissolved by bringing the etching solution according to the first aspect into contact with the object to be processed and impurities such as particles attached to the surface of the object to be processed are removed from the surface of the object to be processed in a short time.

The temperature at which the etching process is performed is not particularly limited as long as the ruthenium is dissolved with the etching solution. Examples of the temperature for the etching process include 20° C. to 60° C. In a case of any of the spray method, the immersion method, and the liquid filling method, the etching rate is increased by increasing the temperature of the etching solution, but it is possible to appropriately select the processing temperature in consideration of suppressing composition changes in the etching solution to be small, or workability, safety, cost, and the like.

The time for performing the etching process may be appropriately selected according to the purpose of the etching process, the amount of ruthenium to be removed by the etching (for example, the thickness of the ruthenium-containing layer, the amount of ruthenium deposits, and the like) and the etching process conditions.

According to the method for processing an object to be processed of the present embodiment described above, an etching process for an object to be processed is performed using an etching solution according to the first aspect described above including orthoperiodic acid as an oxidizing agent and adjusted to pH 3 or higher with ammonia. Since the etching solution is excellent in etching performance with respect to ruthenium, it is possible to quickly perform the etching process for the object to be processed. Therefore, it is possible to suitably use the processing method of the present embodiment for fine processing of a ruthenium-containing layer formed on a substrate, cleaning of a ruthenium substrate, and the like.

### (Method for Manufacturing Semiconductor Element)

The method for manufacturing a semiconductor element according to the third aspect of the present invention includes a step of carrying out an etching process on the object to be processed including ruthenium, using the etching solution according to the first aspect described above.

It is possible to perform the step of carrying out an etching process on the object to be processed including ruthenium in the same manner as the method illustrated in the “(Method for Processing Object to be Processed)” described above. The object to be processed including ruthenium is preferably a substrate having a ruthenium-containing layer. As the substrate, it is possible to use a substrate usually used for semiconductor element production.

### <Other Steps>

The method for manufacturing the semiconductor element of the present embodiment may include other steps in addition to the etching process step described above. The other steps are not particularly limited and examples thereof include known steps performed when manufacturing a semiconductor element. Examples of the steps include a step for forming each structure such as a metal wiring, a gate structure, a source structure, a drain structure, an insulating layer, a ferromagnetic layer, and a nonmagnetic layer (layer formation, etching other than the etching process described above, chemical mechanical polishing, modification, and the like), a resist film formation step, an exposure step, a development step, a heating process step, a cleaning step, an inspection step, and the like, without being limited thereto. It is possible to appropriately perform these other steps before or after the etching process step as necessary.

According to the method for manufacturing a semiconductor element of the present embodiment described above, an etching process for an object to be processed is performed using an etching solution according to the first aspect described above including orthoperiodic acid as an oxidizing agent and adjusted to pH 3 or higher with ammonia. Since the etching solution is excellent in etching performance with respect to ruthenium, it is possible to quickly perform fine processing of the ruthenium-containing layer formed on the substrate and cleaning of the substrate. Therefore, it is possible to suitably use the manufacturing method of the present embodiment for manufacturing a semiconductor element including ruthenium wiring or the like.

### EXAMPLES

A more detailed description will be given below of the present invention with reference to Examples, but the present invention is not limited to these Examples.

### <Preparation of Etching Solution>

### Example 1, Comparative Examples 1 to 6

2 g of orthoperiodic acid was dissolved in water and each basic compound shown in Table 1 was added thereto. While adding a basic compound, the pH of each solution was measured at 23° C. using a pH meter and basic compounds were added thereto to obtain each range of pH 3 to 4, pH 5 to 6, pH 6 to 7, pH 7 to 8, and pH 8 to 9. Thereafter, water was added such that the volume of the whole solution was 100 mL so as to prepare the etching solution of each Example.

TABLE 1

| | Basic Compound |
|---|---|
| Example 1 | Ammonia |
| Comparative Example 1 | Potassium hydroxide |
| Comparative Example 2 | Sodium hydroxide |
| Comparative Example 3 | Tetramethyl ammonium hydroxide |
| Comparative Example 4 | Mono ethanol amine |
| Comparative Example 5 | Ethylene diamine |
| Comparative Example 6 | — |

### [Evaluation of Appearance]

The etching solutions of Example 1 and Comparative Examples 1 to 6 were prepared, the presence or absence of precipitates in the etching solution was visually confirmed, and evaluation was carried out according to the following evaluation criteria. The results are shown in Table 2 as “Appearance”.

### Evaluation Criteria

A: There are no precipitates
B: There are precipitates

### <Etching Process for Object to be Processed>

As the object to be processed, a ruthenium substrate in which a ruthenium film (thickness 30 nm) formed by the ALD method on a 12-inch silicon substrate was used. The etching process was performed by placing the etching solution of each Example in a beaker and the ruthenium substrate was immersed in the etching solution of each Example at room temperature (23° C.).

### [Etching Rate Evaluation]

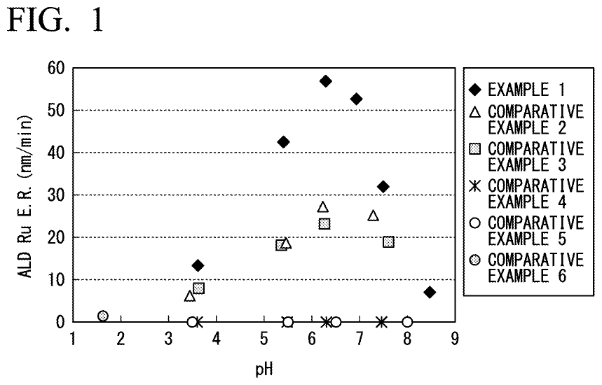

After performing the etching process by the method shown in “<Etching Process for Object to be Processed” above, the object to be processed was taken out from the etching solution and the sheet resistance value of the substrate surface was measured. The etching rate of each Example was calculated from the sheet resistance value. The results are shown in Table 2 as “Etching Rate”. In addition, the relationship between the pH of the etching solution and the etching rate in each Example is shown as a scatter diagram in FIG. 1.

TABLE 2

| | Etching rate (nm/min) | | | | | | |
|---|---|---|---|---|---|---|---|
| | Appearance | pH 1 to 2 | pH 3 to 4 | pH 5 to 6 | pH 6 to 7 | pH 7 to 8 | pH 8 to 9 |
| Example 1 | A | — | 13.4 | 43.5 | 56.9 | 32.0 | 7.2 |
| Comparative | B | — | Precipitate | Precipitate | Precipitate | Precipitate | Precipitate |
| Example 1 | | | | | | | |
| Comparative | A | — | 6.1 | 18.6 | 27.1 | 25.0 | |
| Example 2 | | | | | | | |
| Comparative | A | — | 8.1 | 18.1 | 23.1 | 19.0 | — |
| Example 3 | | | | | | | |
| Comparative | A | — | <0.1 | <0.1 | <0.1 | <0.1 | — |
| Example 4 | | | | | | | |
| Comparative | A | — | <0.1 | <0.1 | <0.1 | <0.1 | — |
| Example 5 | | | | | | | |
| Comparative | A | 1.4 | — | — | — | — | — |
| Example 6 | | | | | | | |

As is apparent from Table 2 and FIG. 1, no precipitates were confirmed in Example 1 and the etching rate was improved as compared with Comparative Examples 1-6. In Example 1, the etching rate was particularly good in the pH range of 5 to 7.

From the above, it is possible to confirm that the etching solutions of the Examples to which the present invention was applied made it possible to etch ruthenium at a good etching rate.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A ruthenium etching solution comprising orthoperiodic acid and ammonia, wherein a pH of the ruthenium etching solution is 3 or higher.

2. The ruthenium etching solution according to claim 1, wherein the pH of the ruthenium etching solution is 12 or lower.

3. A method for processing an object to be processed, the method comprising carrying out an etching process on an object to be processed comprising ruthenium, using the ruthenium etching solution according to claim 1.

4. A method for manufacturing a semiconductor element, the method comprising etching an object to be processed comprising ruthenium using the ruthenium etching solution according to claim 1.
